(19) United States
(12) Patent Application Publication
(10) Pub. No.: US 2009/0189191 A1
(43) Pub. Date: Jul. 30, 2009

(54) SEMICONDUCTOR DEVICE

(75) Inventors: Yoshihiro Sato, Tokyo (JP); Shusuke Kaya, Tokyo (JP)

Correspondence Address: TUROCY & WATSON, LLP, 127 Public Square, 57th Floor, Key Tower, CLEVELAND, OH, 44114, US

(73) Assignee: The Furukawa Electric Co., LTD, Tokyo (JP)

(21) Appl. No.: 12/341,216

(22) Filed: Dec. 22, 2008

(30) Foreign Application Priority Data
Jan. 30, 2008 (JP) 2008-19071

(51) Int. Cl. H01L 29/24; H01L 29/772

(52) U.S. Cl. 257/195; 257/476; 257/E29.1; 257/E29.242

(57) ABSTRACT

A semiconductor device includes a field effect transistor formed of a GaN-based compound semiconductor and having a source electrode, a drain electrode, and a gate electrode, and a diode formed of a semiconductor material having a gandgap energy smaller than a bandgap energy of the GaN-based compound semiconductor. A cathode electrode and an anode electrode of the diode are electrically connected to the source electrode and the gate electrode of the field effect transistor, respectively.

### CROSS-REFERENCE TO RELATED APPLICATIONS

This application claims priority from a Japanese patent application serial No. 2008-19071 filed on Jan. 30, 2008, the entire content of which is incorporated herein by reference.

### BACKGROUND OF THE INVENTION

1. Field of the Invention

The present invention relates to a semiconductor device that realizes a diode having a high breakdown voltage characteristic.

2. Description of the Related Art

A variety of field effect transistors (FET) formed of a GaN-based compound semiconductor such as GaN, InGaN, AlInGaN etc. have been proposed. For example, in the Japanese patent publication No. 2003-179082 is disclosed a high electron mobility transistor (HEMT) formed of a GaN-based compound semiconductor, a kind of GaN-based FET. The GaN-based FET formed of a GaN-based compound semiconductor has a high breakdown voltage characteristic based on a property of the material.

If a diode structure can be formed of a GaN-based compound semiconductor, a diode capable of operating at a large current and with a high breakdown voltage can be realized. However, it has been difficult to fabricate a diode structure using a GaN-based compound semiconductor.

### SUMMARY OF THE INVENTION

It is an object of the present invention to provide a semiconductor device that realizes a diode which has a high breakdown voltage characteristic comparable to GaN-based FET, and which has a low on-resistance.

According to an aspect of the present invention, there is provided a semiconductor device comprising: a field effect transistor formed of a GaN-based compound semiconductor and including a source electrode, a drain electrode, and a gate electrode; and a diode formed of a semiconductor material having a gandgap energy smaller than a bandgap energy of the GaN-based compound semiconductor, and including a cathode electrode electrically connected to the source electrode and an anode electrode electrically connected to the gate electrode.

According to another aspect of the present invention, there is provided a semiconductor device comprising: a silicon substrate to which a diode having an anode electrode and a cathode electrode is formed; and a field effect transistor formed in GaN-based compound semiconductor layers laminated on one surface of the silicon substrate, said field effect transistor including a source electrode, a drain electrode, and a gate electrode, wherein the cathode electrode and the source electrode are electrically connected and the anode electrode and the gate electrode are electrically connected.

The above and other objects, features, advantages and technical and industrial significance of this invention will be better understood by reading the following detailed description of presently preferred embodiment of the invention, when considered in connection with the accompanying drawings.

### BRIEF DESCRIPTION OF THE DRAWINGS

FIG. 1 is a circuit diagram showing a semiconductor device according to an embodiment of the present invention;

FIG. 2 is a graph showing a forward characteristic of the semiconductor device according to the embodiment of the present invention;

FIG. 3 is a graph showing a reverse characteristic of the semiconductor device according to the embodiment of the present invention;

FIG. 4 is a view schematically showing an integrated structure of the semiconductor device according to the embodiment of the present invention; and

FIGS. 5 to 12 are explanatory views showing a manufacturing process of the semiconductor device according to the embodiment of the present invention.

### DETAILED DESCRIPTION OF THE PREFERRED EMBODIMENT

An exemplary embodiment of the semiconductor device of the present invention is explained below with reference to the accompanying drawings. The present invention is not limited by the embodiment. In the drawings, like reference numerals are used for like parts throughout the several views.

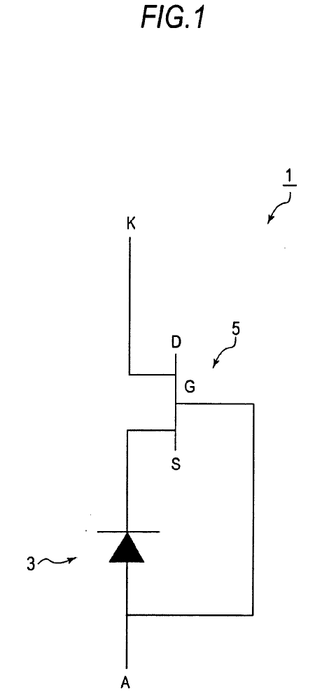

FIG. 1 is a circuit diagram showing a configuration of a semiconductor device 1 according to the present embodiment. As shown in FIG. 1, the semiconductor device 1 according to the embodiment includes a silicon diode 3 having a low breakdown voltage characteristic, and a GaN-based HEMT 5 formed of a GaN-based compound semiconductor, having a high breakdown voltage characteristic and capable of operating with low loss. A source electrode of the GaN-based HEMT 5 is connected to a cathode of the silicon diode 3, and a gate electrode of the GaN-based HEMT 5 is connected to an anode of the silicon diode 3.

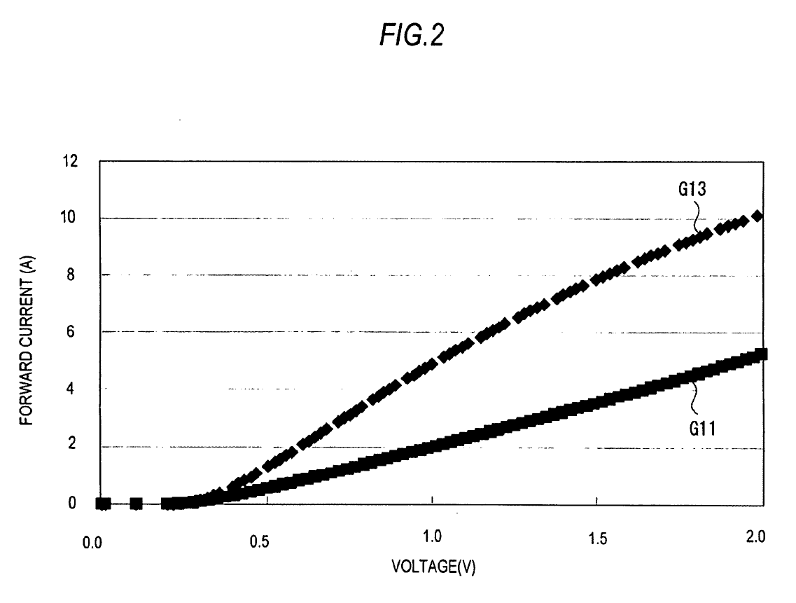

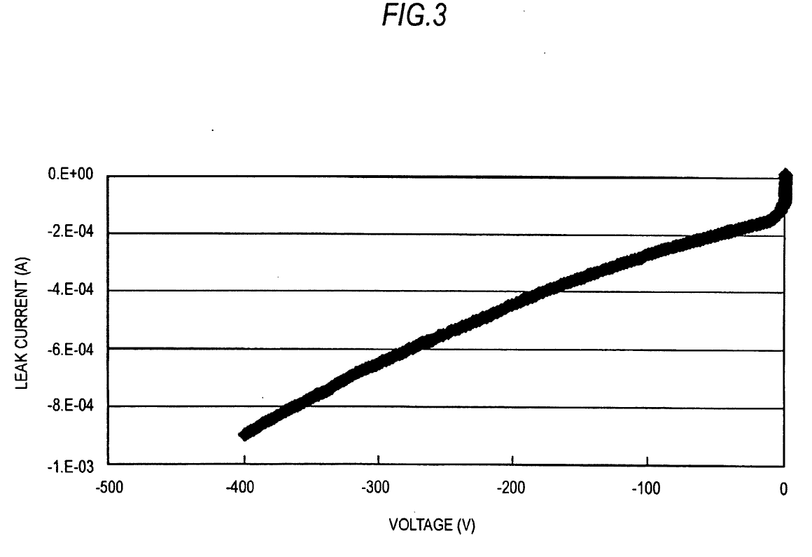

FIG. 2 is a graph showing a forward characteristic G11 of the semiconductor device 1, where a horizontal axis and a vertical axis show a voltage (V) and a forward current (A), respectively. In FIG. 2, a forward characteristic G13 of the silicon diode 3 itself is also shown along with the forward characteristic of the semiconductor device 1. Further, FIG. 3 is a graph showing a reverse characteristic of the semiconductor device 1, where a horizontal axis and a vertical axis show a voltage (V) and a leak current (A), respectively. The semiconductor device 1 has a high breakdown voltage characteristic comparable to a breakdown voltage of the GaN-based HEMT 5 when it is off, and an increase in the leak current can be restrained. Further, a forward resistance of the semiconductor device 1 is a sum of a resistance of the silicon diode 3 and an on-resistance of the GaN-based HEMT 5, and therefore is greater than the resistance of the silicon diode 3 itself. However, the forward resistance of the semiconductor device 1 is smaller than a resistance of a silicon diode having a breakdown voltage characteristic comparable to that of the semiconductor device 1. Further, although a diode formed of a GaN-based compound semiconductor has a high threshold voltage because of its large bandgap energy, a threshold voltage of the semiconductor device 1 according to the present embodiment can be reduced because the semiconductor device 1 utilizes the forward characteristics of the silicon diode 3 formed of silicon having a bandgap energy smaller than a bandgap energy of the GaN-based compound semiconductor.

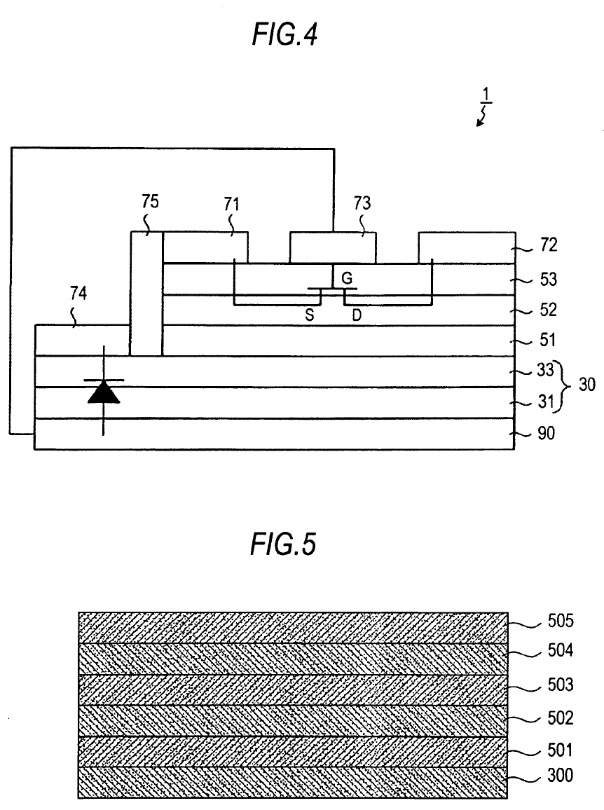

In the present embodiment, the semiconductor device 1 is obtained by integrating a silicon diode and a GaN-based HEMT. FIG. 4 is a view schematically showing an integrated structure of the semiconductor device 1. As shown in FIG. 4, the semiconductor device 1 includes a silicon substrate 30 to which a diodes structure is formed. For example, a p-type Si semiconductor layer 31 and a n-type Si semiconductor layer 33 are laminated to form the silicon diode. A buffer layer 51, a GaN layer 52 and an AlGaN layer 53 are laminated on the silicon substrate 30, and a source electrode 71, a drain electrode 72, and a gate electrode 73 are formed on a part of the AlGaN layer 53, to form the GaN-based HEMT. A portion of the buffer layer 51, the GaN layer 52, and the AlGaN layer near the source electrode 71 is removed to expose the silicon substrate 30. On a part of a surface of the n-type Si semiconductor layer 33 exposed on the top surface of the silicon substrate 30, an electrode 74 as a first conductor layer is formed. The electrode 74 is connected to the source electrode 71 by an electrode layer 75 as a connecting conductor layer, whereby a cathode of the silicon diode is electrically connected to the source electrode 71. Further, a backside electrode 90 as a second conductor layer is formed over an entire surface of the p-type Si semiconductor layer 31 on a backside of the silicon substrate 30. The backside electrode 90 is connected to the gate electrode 73 by wire bonding, whereby an anode of the silicon diode is electrically connected to the gate electrode 73. The semiconductor device 1 functions as a diode having the backside electrode 90 as an anode electrode and the drain electrode 72 as a cathode electrode.

Thus, by using the silicon substrate 30 to which a diode structure is formed and laminating the buffer layer 51, the GaN layer 52, and the AlGaN layer 53 on the silicon substrate 30, the GaN-based HEMT is formed on the cathode-side surface of the silicon substrate 30 so that the silicon diode and the GaN-based HEMT are integrated, whereby an on-resistance of the silicon diode can be lowered. Accordingly, it is possible to realize both a higher breakdown voltage characteristic and a lower on-resistance characteristic, i.e., the semiconductor device 1 can realize an efficient diode having both a high breakdown voltage characteristic and a low on-resistance characteristic. Further, in the semiconductor device 1, the electrode 74 formed on the n-type Si semiconductor layer 33 of the silicon substrate 30 and the source electrode 75 are connected by the electrode layer 75. Accordingly, a wiring resistance between the electrodes can be lowered.

A manufacturing process of the semiconductor device 1 is explained below. FIGS. 5 to 12 are explanatory views showing a manufacturing process of the semiconductor device 1. First, as shown in FIG. 5, a Si(111) substrate 300 to which a diode structure is formed is prepared. An AlN layer 501, a buffer layer 502, a p-GaN layer 503, an undoped GaN(un-GaN) layer 504, and a AlGaN layer 505 are grown in this order on the Si(111) substrate 300, using MOCVD (Metal Organic Chemical Vapor Deposition) method.

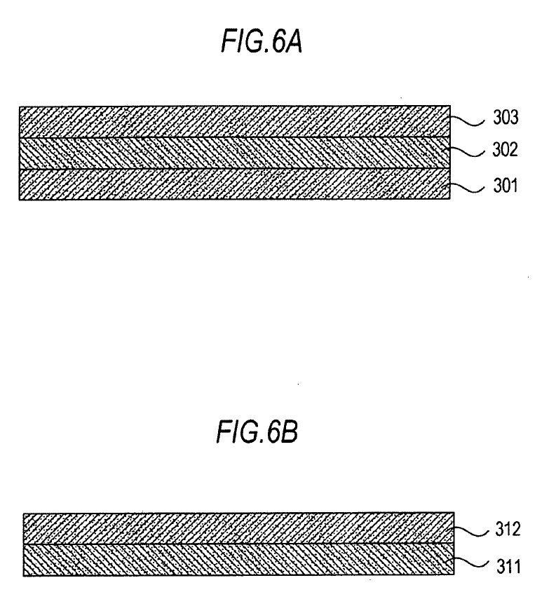

Specifically, a diode structure is formed using an appropriate method such as epitaxial growth, impurity diffusion, ion implantation or the like on a Si(111) substrate. For example, a pn junction diode is formed. FIG. 6A shows a structure of the Si(111) substrate 300 to which a pn junction diode is formed. As shown in FIG. 6A, in the case of forming a pn junction diode, the Si(111) substrate 300 is prepared by forming a diode structure constituted by a p⁺-type diffusion layer 301 of impurity concentration of 1×10¹⁹(cm⁻³), an n⁻-type diffusion layer 302 of impurity concentration of 5×10¹⁶(cm⁻³), and an n⁺-type diffusion layer 303 of impurity concentration of 2×10¹⁹(cm⁻³). The diode structure formed may be a Schottky barrier diode. FIG. 6B shows a structure of the Si(111) substrate to which a Schottky barrier diode is to be formed. As shown in FIG. 6B, in the case of forming a Schottky barrier diode, the Si(111) substrate is prepared by forming a lamination structure constituted by an n⁺-type diffusion layer 311 of impurity concentration of 2×10¹⁹(cm⁻³) and an n-type diffusion layer 312 of impurity concentration of 5×10¹⁶(cm⁻³).

Then, the Si(111) substrate 300 is placed in a MOCVD apparatus. Trimethylgallium (TMGa), trimethylaluminum (TMAl) and ammonia (NH₃) are introduced with flow rates of 58(μmol/min), 100(μmol/min), and 12(l/min), respectively. Thus, an AlN layer 501 of 100 nm in thickness, a buffer layer 502 of eight pairs of GaN/AlN layer structure constituted by a 200 nm-thick GaN layer and a 20 nm-thick AlN layer, and a p-GaN layer 503 of 500 nm in thickness, are epitaxially grown sequentially on the Si(111) substrate 300, at the growth temperature of 1050° C., as shown in FIG. 5.

Thereafter, TMGa and NH₃ are introduced with flow rates of 19(μmol/min), and 12(l/min), respectively, at a growth temperature of 1050° C. to epitaxially grow an un-GaN layer 504 (an electron drift layer) of 100 nm in thickness on the p-GaN layer 503. Further, TMAl, TMGa and NH₃ are introduced with flow rates of 125(μmol/min), 19(μmol/min), and 12(l/min), respectively, at a growth temperature of 1050° C., to epitaxially grow an AlGaN layer 505 (an electron supplying layer) of Al composition of 25% and of 20 nm in thickness on the un-GaN layer 504. In the growth step of each layer, a 100% hydrogen gas is used as a carrier gas to introduce TMAl, TMGa, and NH₃.

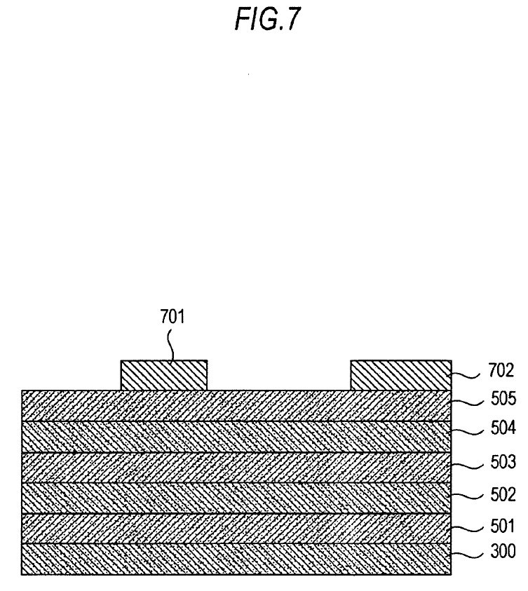

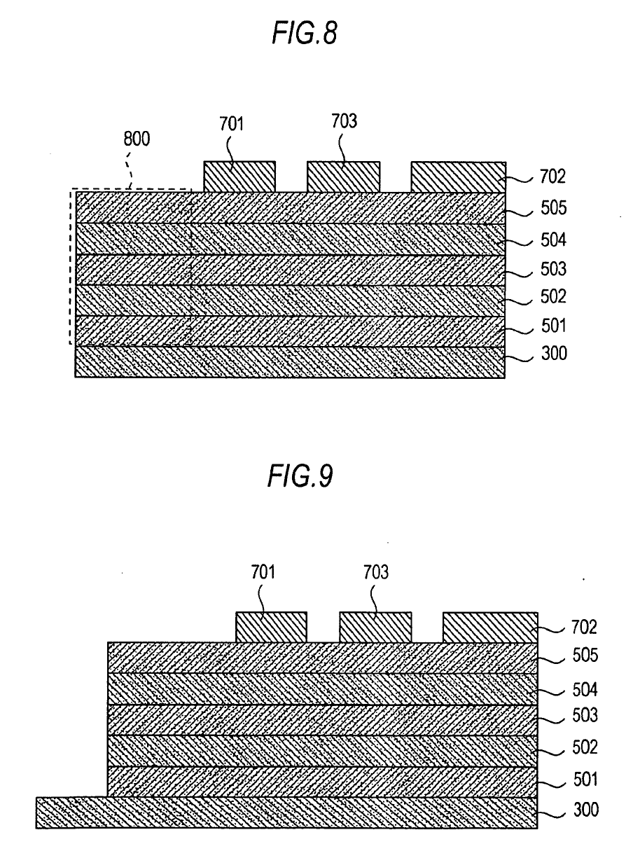

Then, an unillustrated mask layer constituted by SiO₂ film is formed on the AlGaN layer 505. The mask layer is patterned by photolithography, and openings corresponding to shapes of a source electrode and a drain electrode are formed using hydrofluoric acid. Electrode layers constituted by Ti(25 nm)/Al(300 nm) are formed in the openings by suitably using sputtering method or vacuum evaporation method. Then, the electrode layers are formed into the source electrode 701 and the drain electrode 702 by lift off method (see FIG. 7). Thereafter, annealing is performed at 600° C. for 10 minutes. Further, an electrode layer constituted by Ti/Au/Ti is formed by suitably using sputtering method or vacuum evaporation method, which thereafter is formed into a gate electrode 703 using lift off method (see FIG. 8).

Then, a portion 800 near the source electrode 701 located on an opposite side to the gate electrode 703 (see FIG. 8) is removed by dry etching, to expose a top surface of the Si(111) substrate 300 or, specifically, the n⁺-type diffusion layer 303 of FIG. 6A (see FIG. 9). Then, an electrode 704, or a first conductor layer, is formed on the exposed surface of the Si(111) substrate 300, suitably using sputtering method or vacuum evaporation method and lift off method (see FIG. 10). In the case of the diode structure of the Si(111) substrate 300 being a pn junction diode, the electrode 704 is formed of Ti. In the case of the diode structure of the Si(111) substrate being a Schottky barrier diode, the electrode 704 is formed of Pt.

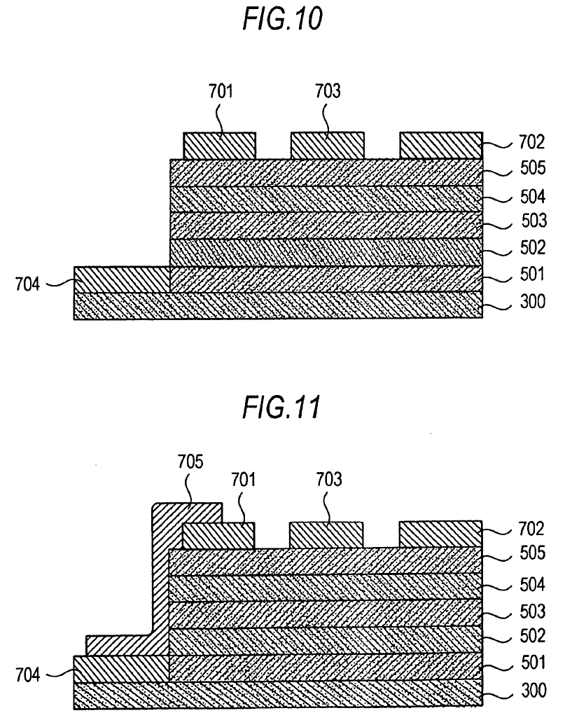

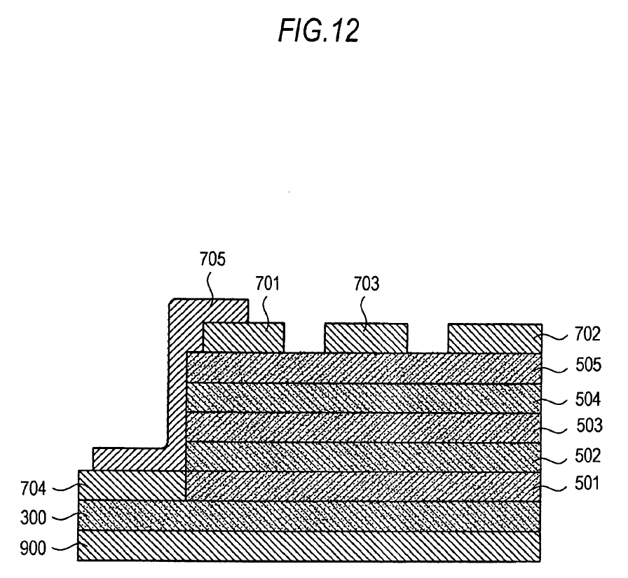

Thereafter, an electrode layer 705, or connecting conductor layer, is formed so as to electrically connect the source electrode 701 and the electrode 704, suitably using sputtering method or vacuum evaporation method and lift off method (see FIG. 11). Then, a backside electrode 900, or a second conductor layer, constituted by Ti/Ni/Au is formed on the backside of the Si(111) substrate 300, or specifically, on a surface of the p⁺-type diffusion layer 301 of FIG. 6A, suitably using sputtering method or vacuum evaporation method (see FIG. 12). Thereafter, elements are separated using a dicer and each element is packaged. When each element is packaged, the gate electrode 703 and the backside electrode 900 on the backside surface of the Si(111) substrate 300 are connected by wire bonding, although the process is not shown in the figures.

As described above, the semiconductor device 1 according to the present embodiment can realize a diode having a large breakdown voltage characteristic comparable to that of GaN-based HEMT and a low on-resistance, and which is capable of operating at a large current.

In the above-described embodiment, a GaN-based HEMT formed of GaN-based compound semiconductor is used as an example of a GaN-based FET. However, a variety of FETs formed of GaN-based compound semiconductor may be used in place of the GaN-based HEMT. Further, in the above-described embodiment, a silicon diode is used as an example of a diode having a low breakdown voltage characteristic. However, the diode is not limited to a silicon diode. The effect of the present invention is enjoyed as long as a breakdown voltage of the GaN-based FET is higher than that of the diode used.

Further, in the above-described embodiment, a GaN-based HEMT the compound semiconductor layer of which is formed of GaN and AlGaN is used. However, a GaN-based FET formed of a GaN-based compound semiconductor to which other elements are added, such as InGaN or AlInGaN etc, may be properly used.

Further, in the above-described embodiment, the cathode side surface of the silicon substrate, to which the diode structure is formed, is exposed and the electrode is formed on the exposed surface. The electrode layer is formed to connect the electrode and the source electrode. However, the electrode and the source electrode may be connected by wire bonding.

As described above, the semiconductor device according to the present invention includes a field effect transistor formed of a GaN-based compound semiconductor and a diode formed of a semiconductor material having a band gap energy smaller than that of the GaN-based compound semiconductor. Accordingly, the semiconductor device according to the present invention can realize a diode having a high breakdown voltage characteristic and a low on-resistance.

Although the invention has been described with respect to specific embodiment for a complete and clear disclosure, the appended claims are not to be thus limited but are to be construed as embodying all modifications and alternative constructions that may occur to one skilled in the art that fairly fall within the basic teaching herein set forth.

What is claimed is:

1. A semiconductor device comprising:
a field effect transistor formed of a GaN-based compound semiconductor and including a source electrode, a drain electrode, and a gate electrode; and
a diode formed of a semiconductor material having a gandgap energy smaller than a bandgap energy of the GaN-based compound semiconductor, and including a cathode electrode electrically connected to the source electrode and an anode electrode electrically connected to the gate electrode.

2. The semiconductor device according to claim 1, wherein the semiconductor material is silicon.

3. A semiconductor device comprising:
a silicon substrate to which a diode having an anode electrode and a cathode electrode is formed; and
a field effect transistor formed in GaN-based compound semiconductor layers laminated on one surface of the silicon substrate, said field effect transistor including a source electrode, a drain electrode, and a gate electrode,
wherein the cathode electrode and the source electrode are electrically connected and the anode electrode and the gate electrode are electrically connected.

4. The semiconductor device according to claim 3, wherein said field effect transistor includes a GaN layer and an AlGaN layer laminated on the GaN layer.

5. The semiconductor device according to claim 3, wherein the diode is a pn junction diode.

6. The semiconductor device according to claim 3, wherein the diode includes a Si layer of a first conductivity type and another Si layer of a second conductivity type formed on the Si layer of the first conductivity type.

7. The semiconductor device according to claim 3, wherein the diode is a Schottky barrier diode.
